(19) United States
(12) Patent Application Publication
(10) Pub. No.: US 2002/0109216 A1
(43) Pub. Date: Aug. 15, 2002

(54) Integrated electronic device and integration method

(76) Inventors: Yuko Matsuzaki, Kanagawa (JP); Hiroyuki Fukasawa, Tokyo (JP)

Correspondence Address: SONNENSCHEIN NATH & ROSENTHAL, P.O. BOX 061080, WACKER DRIVE STATION, CHICAGO, IL, 60606-1080, US

(21) Appl. No.: 10/034,944

(22) Filed: Dec. 27, 2001

(30) Foreign Application Priority Data
Dec. 27, 2000 (JP) P2000-398715

(51) Int. Cl. H01L 21/44; H01L 23/02; H01L 29/40

(52) U.S. Cl. 257/686; 257/787; 257/777; 257/784; 438/617; 438/112; 438/109; 257/696

(57) ABSTRACT

An integrated electronic device has at least two semiconductor devices built up in a multi-layer construction on a wiring substrate in which a die pad and a plurality of electrode pads are formed, the semiconductor device having a plurality of electrodes formed thereon. The semiconductor device for a first stage is disposed on the die pad. The semiconductor device for a second stage is disposed on the top of the first stage semiconductor device with having an electrically insulating resin layer in between the first and second stage semiconductor devices. The electrodes of the semiconductor devices are wire-bonded with corresponding electrode pads, and all of the build-up semiconductor devices and their wires are sealed with insulating seal resin.

### RELATED APPLICATION DATA

This application claims priority to Japanese Patent Application JP 2000-398715, and the disclosure of that application is incorporated herein by reference to the extent permitted by law.

### BACKGROUND OF THE INVENTION

1. Field of the Invention

The present invention relates to a semiconductor device and a fabrication method, specifically an integrated electronic device and its integration method in which layers of semiconductor devices are built up in a multi-layer construction.

2. Description of the Related Art

An integrated electronic device including a semiconductor device and its integration method in related art will now be described with reference to FIG. 3 to FIG. 6.

FIG. 3 is a cross sectional side view of an integrated electronic device in related art. FIGS. 4A, 4B are illustrations of a semiconductor device mounted on TAB film carrier. FIG. 4A is the plan view and FIG. 4B is the cross sectional side view taken along the line B-B shown in FIG. 4A. FIG. 5 is a cross sectional side view of the integrated electronic device in the related art shown in FIG. 3 at one step of integration process in which a plurality of semiconductor devices shown in FIG. 4A and FIG. 4B are built up in a multi-layer construction. FIG. 6 is a cross sectional side view of the integrated electronic device at one step of the integration process following the integration process step shown in FIG. 5, the integration process step in which a plurality of semiconductor devices are being integrated.

In FIG. 3, an integrated electronic device 40 of the related art comprises a wiring substrate 41 and a plurality of semiconductor device 42. There are four semiconductor devices 42A, 42B, 42C and 42D in the example shown in the figure.

An electrode pad 411 and a plurality of die pads 412 are formed on a mounting side of the wiring substrate 41. The plurality of die pads 412 are provided so as to surround the electrode pad 411. Each of semiconductor devices is so-called a bare chip in which a plurality of electrodes 421 are formed on peripheral part of its surface.

The integrated electronic device 40 is fabricated in the following manner. The semiconductor device 42A at the first stage (bottom) is die-bonded at the die pad 412 of the wiring substrate. The semiconductor device 42B at the second stage is formed on the top of the semiconductor device 42A with having a predetermined gap in between. The semiconductor devices 42C, 42D at the third, fourth stage are similarly formed. One ends of TAB leads 43A, 42B, 42C, 42D are connected to respective electrodes 421, and the other ends are connected to corresponding electrode pads 411 formed on the wiring substrate 41. The integrated electronic device 40 is completed by sealing overall construction of layered or build-up (hereafter these structures are called by a generic term “integrated”) semiconductor devices 42A, 42B, 42C, 42D with insulating seal resin 44.

An integration method of the integrated electronic device 40 will now be described with reference to FIG. 4A to FIG. 6.

As shown in FIG. 4A and FIG. 4B, inner leads 46 of TAB film carrier 45 are connected to the semiconductor device 42 by utilizing a transfer bump method. Some of outer leads 47 of the TAB film carrier 45 are cut to terminate connections to non-common electrodes such as write-enable electrodes or read-enable electrodes in the semiconductor device 42.

Next, as shown in FIG. 5, the first stage semiconductor device 42A mounted in the TAB film carrier is die-bonded on the die pad 412 of the wiring substrate 41 using a plurality of positioning pins 48. Subsequently, the second stage semiconductor device 42B, the third stage semiconductor device 42C, and the fourth stage semiconductor device 42D are mounted on the top of the preceding semiconductor devices with having a predetermined distance between two semiconductor devices. Each of the electrode pads 411 of the wiring substrate 41 and corresponding outer leads 47 of the TAB film carrier 45 for each semiconductor device 42 are aligned and connected before the next stage of the semiconductor device is mounted thereon.

Next, as shown in FIG. 6, all of the outer leads 47 and the electrode pads 411 of the wiring substrate 41 pressed and heated by a bonding tool 49 to perform the bonding processing.

Finally, outer taping part of the outer leads 47 is removed, and an over all structure that has been constructed is sealed with the insulating seal resin 44 to complete the construction of the integrated electronic device 40 as shown in FIG. 3.

### SUMMARY OF THE INVENTION

However, in the integrated electronic device of the related art, precise alignment utilizing a plurality of positioning pins is required to position the outer leads 47 and the electrode pads 411 of the wiring substrate 41. Furthermore, the bonding tool 49 has to be custom-designed for bonding the outer leads 47 to the electrode pads 411.

The present invention is made to address the above mentioned topics. It is desirable to provide an integrated electronic device and its integration method that can eliminate jigs and/or complex alignment step for positioning the outer leads and corresponding electrode pads of a wiring substrate. Furthermore, it is desirable to provide an integrated electronic device and its integration method that does not require a special bonding tool for connecting electrodes of a semiconductor device and electrode pads of the wiring substrate. Furthermore, it is desirable to provide an integrated electronic device and its integration method in which a plurality of semiconductor devices are built up in a multi-layer construction of a lower profile.

In the first embodiment of the present invention, there is provided an integrated electronic device having at least two semiconductor devices built up in a multi-layer construction on a wiring substrate in which a die pad and a plurality of electrode pads are formed. The semiconductor device has a plurality of electrodes formed thereon. In the integrated electronic device, the semiconductor device for the first stage is disposed on the die pad. The semiconductor device for the second stage is disposed on the top of the semiconductor device of the first stage with having an electrically insulating resin layer in between the first and second stage semiconductor devices. The electrodes of the semiconductor devices are wire-bonded with corresponding electrode pads. Finally, overall structure of the build-up semiconductor devices and the wires are sealed with insulating seal resin.

In the second embodiment of the present invention, the electrically insulating resin layer of the integrated electronic device in the first embodiment may be formed with a thermosetting resin sheet member containing insulation fillers in which electrically insulating material is mixed in as fillers. Alternatively, the thermosetting resin layer containing insulation fillers may be formed by utilizing thermosetting resin member shaped into a sheet-like form or a thermosetting resin sheet/film.

In the third embodiment of the present invention, the electrically insulating material of the integrated electronic device in the second embodiment may be fused or fractured silica. Furthermore, the thermosetting resin material of the integrated electronic device in the second embodiment may be epoxy resin.

In the fourth embodiment of the present invention, there is provided an integration method of an integrated electronic device having at least two semiconductor devices built up in a multi-layer construction on a wiring substrate in which a die pad and a plurality of electrode pads are formed. The semiconductor device has a plurality of electrodes formed thereon. In the integration method, the following steps are carried out: (1) die-bonding the first semiconductor device on the die pad of the wiring substrate; (2) wire-bonding electrodes of the first semiconductor device on corresponding electrode pads formed on the wiring substrate thereby completing a first stage layer; (3) covering the first semiconductor device with a sheet containing insulation fillers; (4) die-bonding the second semiconductor device on the sheet containing insulation fillers; (5) wire-bonding electrodes of the second semiconductor device on corresponding electrode pads formed on the wiring substrate thereby completing the second stage layer; (6) repeating steps (3)-(5) as many times as necessary; and (7) sealing overall construction of the build-up semiconductor devices with insulating seal resin.

In the fifth embodiment of the present invention, the sheet containing insulation fillers used in the step of the integration method of the fourth embodiment may comprise thermosetting insulating resin and be fused by heating.

In the sixth embodiment of the present invention, the integration method of the fourth embodiment may further comprising a wire process step for bending the wires of the build-up semiconductor devices so that the wires are laid substantially along external peripheral part of the build-up semiconductor devices. The wire process step may be executed before the sealing step is performed.

According to the first embodiment of the present invention, a plurality of semiconductor devices may be built up in a simple multi-layer construction on an general-purpose wiring substrate without using any TAB film carrier nor lead frame.

According to the second embodiment of the present invention, in addition to the features and advantages of the first embodiment, an integrated electronic device with a lower profile may be realized since the layers of the semiconductor devices are built up with having a thin gap of substantially same thickness between the layers by using the resin sheet containing insulation fillers. Furthermore, an inexpensive integrated electronic device may be provided due to an increase of processing efficiency.

According to the third embodiment of the present invention, in addition to the features and advantages of the second embodiment, an electrical insulation characteristics between the layers of semiconductor devices may be improved.

According to the fourth embodiment of an integration method of an integrated electronic device in accordance with the present invention, a plurality of semiconductor devices may be built up in a simple multi-layer construction on an general-purpose wiring substrate using a commonly used bonding technology without using any TAB film carrier nor lead frame. Furthermore, thickness of the integrated electronic device may be reduced because of promoted integration process efficiency when the resin sheet containing the insulation fillers is used to electrically insulate one layer from the other.

According to the fifth embodiment of an integration method of an integrated electronic device in accordance with the present invention, in addition to the features and advantages of the fourth embodiment, the integration processing efficiency is further promoted since the electrical insulation may be achieved by heating at a relatively low temperature.

According to the sixth embodiment of an integration method of an integrated electronic device in accordance with the present invention, in addition to the features and advantages of the fourth embodiment, the integrated electronic device may be manufactured in a smaller size.

### BRIEF DESCRIPTION OF THE DRAWINGS

The other objects, features and advantages of the present invention will become more apparent from the following description of the presently preferred exemplary embodiments of the invention taken in conjunction with the accompanying drawings, in which:

FIG. 1 shows a perspective view of an integrated electronic device in an embodiment of the present invention;

FIG. 2A shows cross sectional side views of the integrated electronic device shown in FIG. 1 taken along the line B-B.

FIG. 2B is an expanded view of an encircled part in FIG. 2A;

FIG. 3 is a cross sectional side view of an integrated electronic device in related art;

FIG. 4A and FIG. 4B are illustrations of semiconductor device mounted on TAB film carrier. FIG. 4A is the plan view. FIG. 4B is the cross sectional side view taken along the line B-B shown in FIG. 4A;

FIG. 5 is a cross sectional side view of the integrated electronic device in related art shown in FIG. 3 at an integration process step in which a plurality of semiconductor devices shown in FIGS. 4A, 4B are built up in a multi-layer construction; and

FIG. 6 is a cross sectional side view of the integrated electronic device at an integration process step following the integration process step shown in FIG. 5.

### DESCRIPTION OF THE PREFERRED EMBODIMENTS

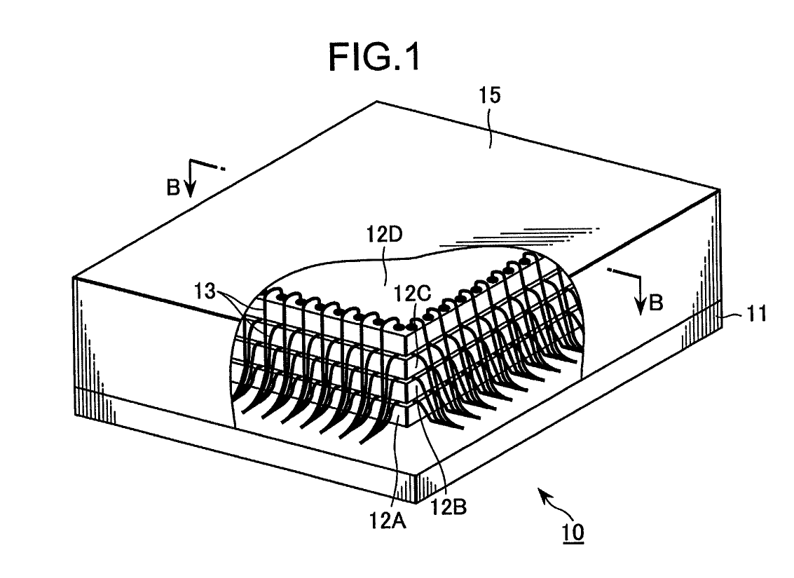

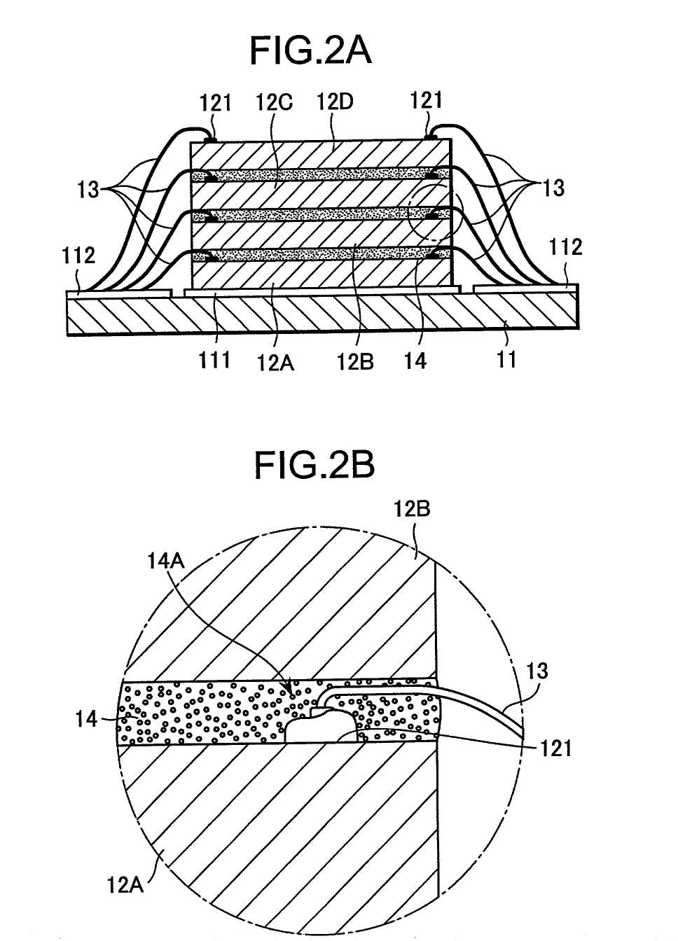

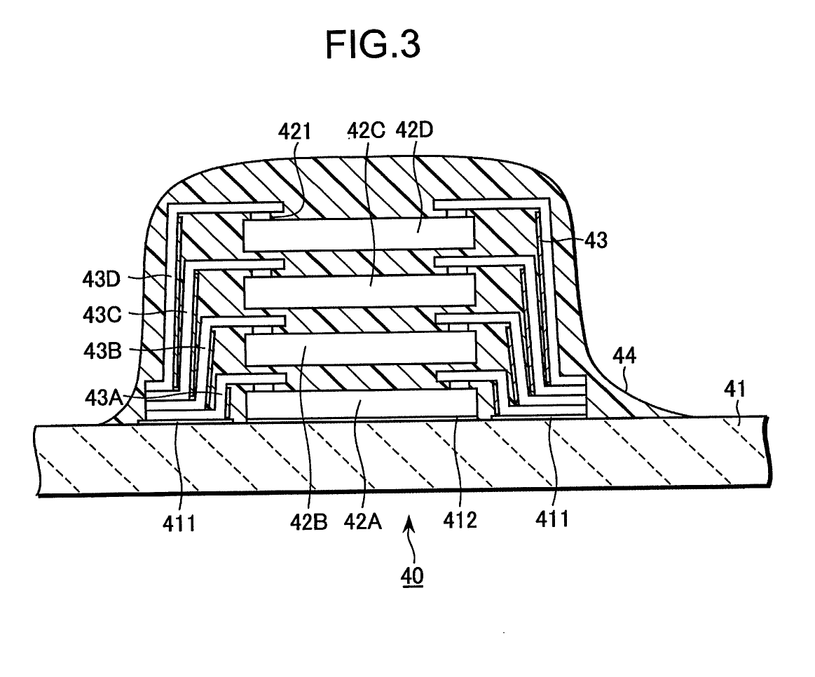

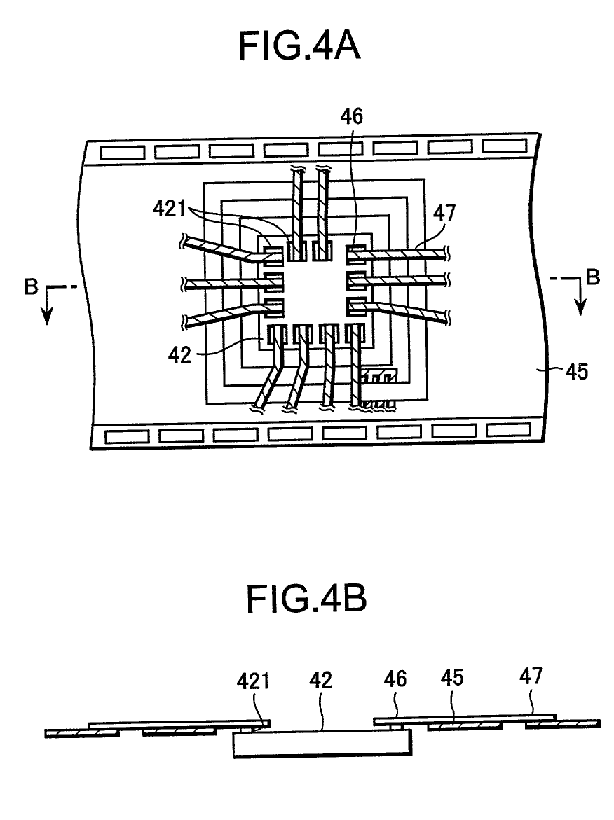

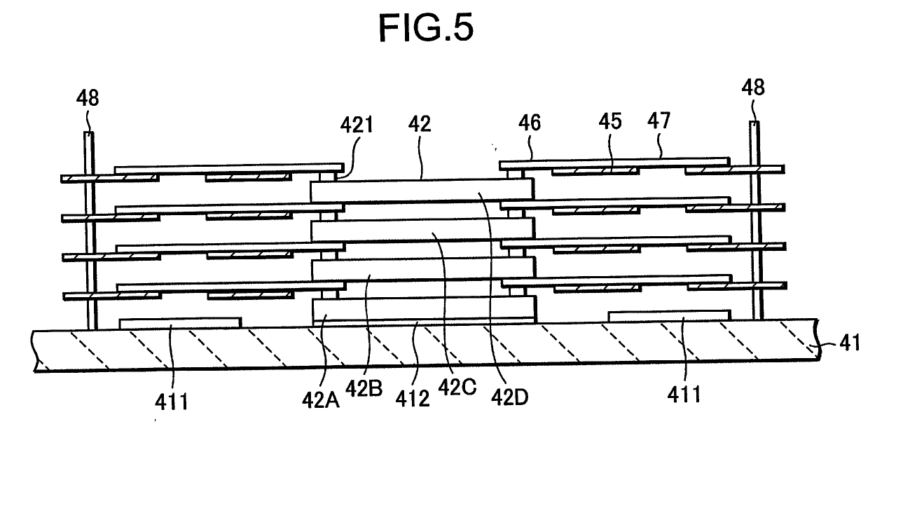

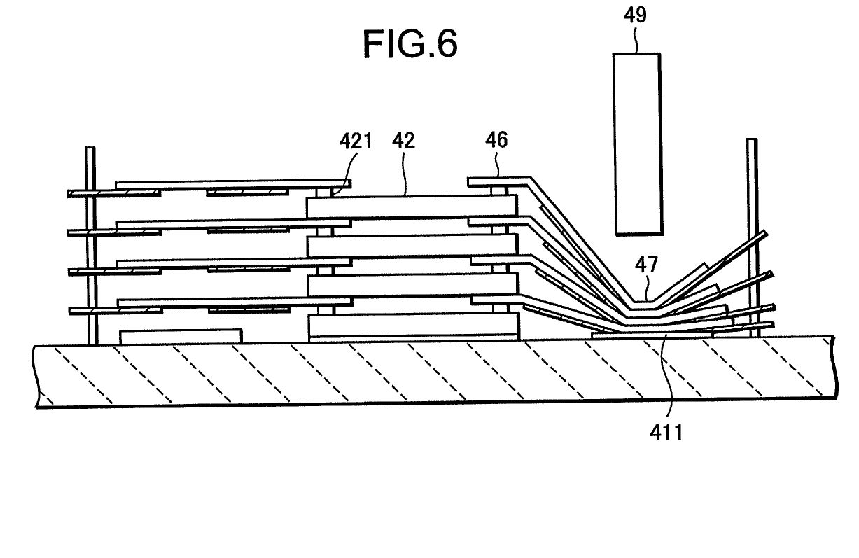

An integrated electronic device and its integration method in accordance with the present invention will now be described with reference to FIG. 1, FIG. 2A and FIG. 2B.

FIG. 1 shows a perspective view of an integrated electronic device in an embodiment of the present invention. FIG. 2A and FIG. 2B show cross sectional side views of the integrated electronic device shown in FIG. 1 taken along the line B-B. FIG. 2A is the overall view and FIG. 2B is the expanded view of an encircled part in FIG. 2A.

In FIG. 1, the integrated electronic device according to the present embodiment is denoted by numeral 10. The integrated electronic device 10 comprises a wiring substrate 11, two or more semiconductor devices 12 (four semiconductor devices are shown in an example of the figure), and an insulating resin layer with insulation fillers.

A plurality of electrodes 121 are formed on an active side surface of each of the semiconductor devices 12. The semiconductor devices 12 are not necessarily of the same type nor the same size.

A die pad 111 and a plurality of electrode pads 112 are formed in advance on a mounting side of the wiring substrate 11 by using various conventional technologies. Here, the plurality of electrode pads 112 are disposed around the die pad 121, and the semiconductor devices 12 are mounted on the mounting side of the wiring substrate 11.

A semiconductor device 12A for the first stage (bottom) is attached on the die pad 111 of the wiring substrate 11. A semiconductor device 12B for the second stage is mounted and attached on the first stage semiconductor device 12A via an insulating resin layer 14 that is disposed on the first stage semiconductor 12A. The second stage semiconductor device 12B may be of the same type or different type from the first stage semiconductor device 12A. A semiconductor device 12C for the third stage and a semiconductor device 12D for the fourth stage are similarly mounted and attached on the respective preceding stage semiconductor device via the insulating resin layer 14.

Electrodes 121 for each of the attached semiconductor devices 12A, 12B, 12C and 12D are wire-bonded with corresponding electrode pads 112 disposed on the wiring substrate 11 with using gold wires 13.

Overall structure of the plurality of the semiconductor devices 12 that have been built up as described above is sealed with insulating seal resin 15.

Next, an integration method of the integrated electronic device 10 will be described with reference to FIG. 1 and FIGS. 2A, 2B.

First, die bond adhesive is applied on the die pad, and then the semiconductor device 12A for the first stage (bottom) is die-bonded on the die pad of the wiring substrate.

Next, electrodes of the semiconductor device 12A are wire-bonded to corresponding electrode pads 112 of the wiring substrate 11. For example, electrodes 121 such as a write-enable electrode and a read-enable electrode are wired bonded to corresponding electrode pads 112 with using the gold wires 13, and an address electrode, a data electrode, a power electrode, ground electrode or the like is wire-bonded to a common electrode of the electrode pads 112.

The insulating resin layer 14 is formed by placing an heated insulating sheet such as a thermosetting insulating resin sheet on the first stage semiconductor device 12A, and further by pressing the insulating sheet to adhere. The die bond adhesive is applied on a surface of the insulating resin layer 14, and the second stage semiconductor device 12B is die-bonded thereon. The gold wires 13 that are wire-bonded to the electrode 121 are pressed downward so as that the gold wires 13 are bended to conform a shape of the semiconductor device 12A when the insulating sheet is heated and pressed to adhere and the second stage semiconductor device 12B is die-bonded.

The same process step as the step used for building-up the second stage semiconductor device 12B is repeated to build-up the semiconductor devices 12C, 12D and so on.

Finally, overall structure of the build-up semiconductor devices are sealed with insulating seal resin 15 by utilizing potting or transfer mold process.

According to the above cited process steps, the integrated electronic device 10 shown in FIG. 1 is completed.

Overall thickness of the integrated electronic device 10 may be reduced by grinding the rear surface (a non-active side surface) of each semiconductor device 12 to reduce its thickness when the semiconductor devices are being built up.

As to material for the insulating resin layer 14, fused silica or fractured silica may be used for the electrically insulating material while epoxy resin may be used for the thermosetting resin. It is preferred to use a sheet containing insulation fillers formed by uniformly mixing the fused silica or fractured silica as filler 14A into the epoxy resin. The insulating resin layer 14 may be formed by covering the semiconductor device 12 with the sheet containing the insulation fillers, and heating the sheet within a temperature range of 150-180° C. so that the sheet is fused and cured. According to these process steps, the insulating resin layer 14 is formed.

In the above-cited embodiments of the present invention, there is no need to perform the precise alignment for positioning the outer leads 47 and the electrode pads 411 of the wiring substrate 41, nor to use the specially designed bonding tool 49 for bonding of the outer leads 47.

The above-cited embodiments of the present invention are described for the integrated electronic device in which only the semiconductor devices are used as the electronic devices to be integrated. Alternatively, other types of electronic devices such as resistor devices and/or capacitor devices may also be included as device to be integrated in the present invention.

According to the above-cited embodiments of the present invention, a simple and inexpensive electrical insulation between the semiconductor devices may be realized by disposing the electrically insulating layer between the semiconductor devices without using costly wiring substrates. Furthermore, according to the above-cited embodiments of the present invention, other features and advantages such as realization of the thinner integrated electronic device with utilizing a conventional wire bonding technology may be provided as well.

While the present invention has been particularly shown and described with reference to embodiments according to the present invention, it will be understood by those skilled in the art that other changes in form and details can be made therein without departing from the essential character thereof.

What is claimed is:

1. An integrated electronic device having at least two semiconductor devices built up in a multi-layer construction on a wiring substrate in which a die pad and a plurality of electrode pads are formed, the semiconductor device having a plurality of electrodes formed thereon, wherein:
said semiconductor device for a first stage is disposed on said die pad,
said semiconductor device for a second stage is disposed on said semiconductor device for a first stage with having an electrically insulating resin layer in between said semiconductor devices for the first stage and the second stage,
said electrodes of said semiconductor devices are wire-bonded with corresponding electrode pads, and
overall structure of said build-up semiconductor devices and said wires are sealed with insulating seal resin.

2. The integrated electronic device according to claim 1, wherein
said electrically insulating resin layer is formed by using a thermosetting resin sheet member containing insulation fillers in which electrically insulating material is mixed in as filler.

3. The integrated electronic device according to claim 2, wherein
said electrically insulating material is fused or fractured silica, and said thermosetting resin is epoxy resin.

4. An integration method of an integrated electronic device having at least two semiconductor devices built up in a multi-layer construction on a wiring substrate in which a die pad and a plurality of electrode pads are formed, the semiconductor device having a plurality of electrodes formed thereon, the integration method comprising:
(1) die-bonding a first semiconductor device on said die pad of said wiring substrate,
(2) wire-bonding electrodes of said first semiconductor device on corresponding electrode pads formed on said wiring substrate thereby completing a first stage layer,
(3) covering said first semiconductor device with a sheet containing insulation fillers,
(4) die-bonding a second semiconductor device on said sheet containing insulation fillers,
(5) wire-bonding electrodes of said second semiconductor device on corresponding electrode pads formed on said wiring substrate thereby completing a second stage layer,
(6) repeating steps (3)-(5) as many times as necessary, and
(7) sealing overall construction of the build-up semiconductor devices with insulating seal resin.

5. The integration method according to claim 4, wherein
said sheet containing insulation fillers comprises thermosetting insulating resin and be fused by heating.

6. The integration method according to claim 4, further comprising:
bending the wires of the build-up semiconductor devices so that the wires are laid substantially along external peripheral part of the build-up semiconductor devices before said sealing is performed.
